(19) United States
(12) Patent Application Publication
(10) Pub. No.: US 2019/0317275 A1
(43) Pub. Date: Oct. 17, 2019

(54) DISPLAY ASSEMBLY INCLUDING AT LEAST TWO DISPLAY DEVICES

(71) Applicant: SEAMLESS TECHNOLOGY INC., Taipei (TW)

(72) Inventors: I-WEI WU, New Taipei (TW); CHIH-LUNG HUNG, New Taipei (TW)

(21) Appl. No.: 16/358,002

(22) Filed: Mar. 19, 2019

Related U.S. Application Data
(60) Provisional application No. 62/655,817, filed on Apr. 11, 2018.

(51) Int. Cl. G02B 6/08; H05K 5/00

(52) U.S. Cl. CPC G02B 6/08; H05K 5/0021; H05K 5/0017

(57) ABSTRACT

A display assembly includes at least two display devices and two image compensating elements at a junction of every adjacent two display devices. Each display device includes a front surface that is viewed by user. Two front surfaces of adjacent two display devices intersect to form an angle of less than 180 degrees. Each front surface defines a display area and a border area. Each image compensating element is on the front surface. Each image compensating element includes a light-incident surface covering the display area, a light-emitting surface coupling to the light-incident surface, and a connecting surface coupling between the light-incident surface and the light-emitting surface. Each image compensating element includes a plurality of light guiding channels. Light guiding paths of the light guiding channels extend along a direction from the light-incident surface toward the light-emitting surface.

### FIELD

The subject matter herein generally relates to a display assembly including at least two display devices.

### BACKGROUND

To realize a large display screen, a plurality of display devices can be coupled (referred to as “splicing”) together to realize a single large display. Each display device has a display area in which a plurality of display pixels are arranged and a border area surrounding the display area. However, when several display devices are spliced together, the border areas become grids imposed over the full display image. The display images are presented to viewers as non-continuous images.

Therefore, there is room for improvement in the art.

### BRIEF DESCRIPTION OF THE DRAWINGS

Implementations of the present technology will now be described, by way of embodiments only, with reference to the attached figures.

FIG. 1 is a top view of a display assembly according to a first embodiment of the present disclosure.

FIG. 2 is a front view of the display assembly of FIG. 1.

FIG. 3 is an enlarged view of area III of FIG. 1.

FIG. 4 is a top view of a display assembly according to a second embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “coupled” is defined as coupled, whether directly or indirectly through intervening components, and is not necessarily limited to physical connections. The connection can be such that the objects are permanently coupled or releasably coupled. The term “comprising” when utilized, means “including, but not necessarily limited to”; it specifically indicates open-ended inclusion or membership in the so-described combination, group, series, and the like.

### FIRST EMBODIMENT

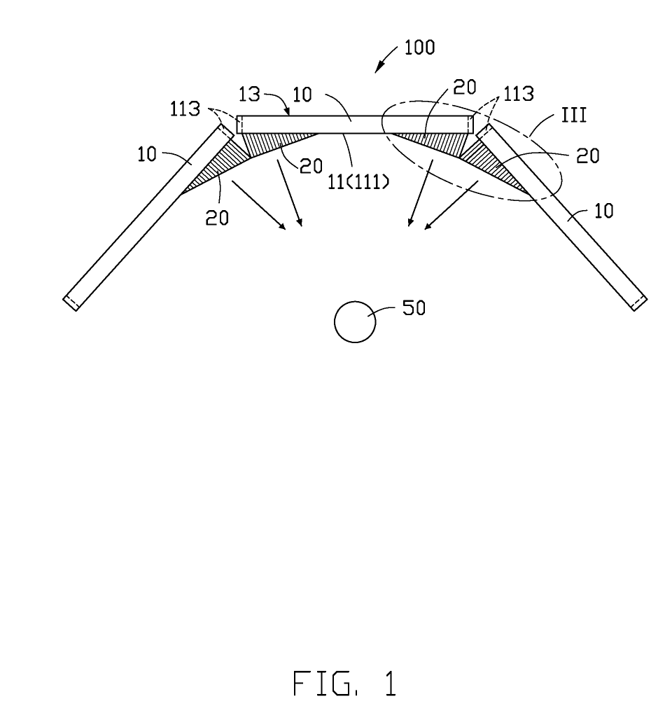

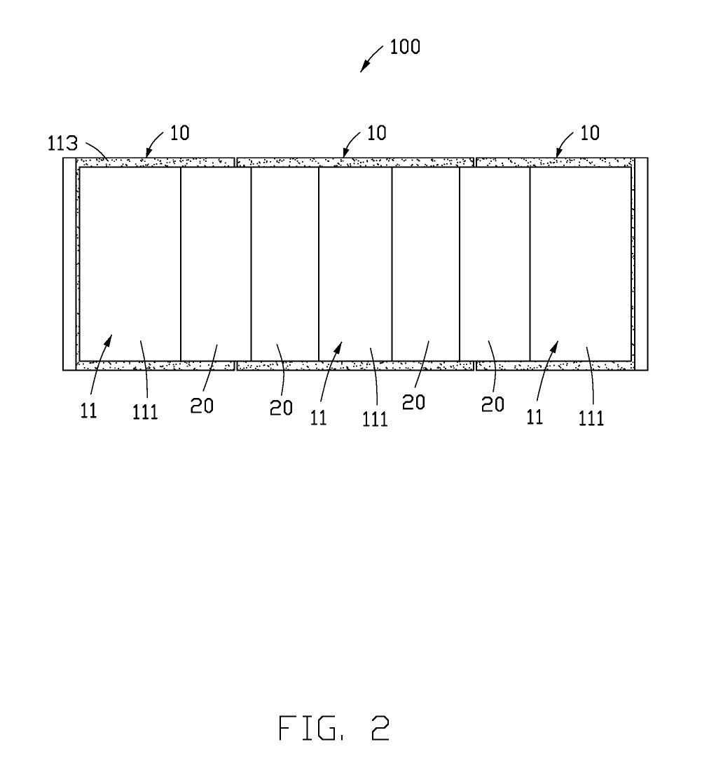

FIG. 1 and FIG. 2 illustrate a display assembly 100 of an embodiment. The display assembly includes three display devices 10 arranged in the manner of a triptych. In other words, the display assembly 100 includes one display device 10 in the middle, one display device 10 on the left side, and one display device 10 on the right side Adjacent display devices 10 are not arranged in one plane, but are tilted at an angle of less than 180 degrees from each other. Each display device 10 includes a front surface 11 and a back surface 13 opposite to the front surface 11. The front surface 11 is viewable and may be touchable by users. The front surface 11 defines a display area 111 for displaying images and a border area 113 outside the display area 111. The border area 113 surrounds the display area 111. In the present embodiment, the border area 113 is on both sides of the display area 111. The two front surfaces 11 of adjacent display devices 10 intersect at an angle of less than 180 degrees.

The number of the display devices 10 in the display assembly 100 is not limited to three. In other embodiments, the display assembly 100 may include two display devices 10 or four display devices 10, as long as the number of the display devices 10 is equal to or greater than two.

When adjacent display devices 10 are spliced together, the two border areas 113 of the two display devices 10 are at a junction of the two display devices 10. In the present embodiment, the two border areas 113 of the two display devices 10 may be spaced apart from each other. In other embodiments, the two border areas 113 of the two display devices 10 are in contact with each other.

As shown in FIG. 1, at least one image compensation component 20 is provided on the front surface 11 of each display device 10 in order to present a continuous or non-interrupted display by the display assembly 100 without being affected by the border areas 113 of the display devices 10. That is to say, no internal borders between the display devices 10 are viewable from the front surfaces 11. The image compensation component 20 can transmit a portion of images such that the images from different display devices 10 are spliced together to form a continuous and non-reticulated display viewable from the front surfaces 11 of the display devices 10. The display assembly 100 can thus display an image without the border areas 113 interrupting the image.

Referring to FIG. 1 and FIG. 2, two image compensating elements 20 are disposed at a junction of adjacent display devices 10, and one image compensating element 20 is located on one display device 10. Each of the image compensating elements 20 is on the front surface 11, within the display area 111, and adjacent to the border area 113 of the display device 10. The image compensating element 20 does not contact the border area 113 of the front surface 11 but effectively overhangs and hides the border area 13. In the present embodiment, a portion of the display area 111 that is not covered by the image compensating element 20 is defined as a main display area, and other portion of the display area 111 that is covered by the image compensating element 20 is defined as an infill display area. The infill display area is outside of the main display area.

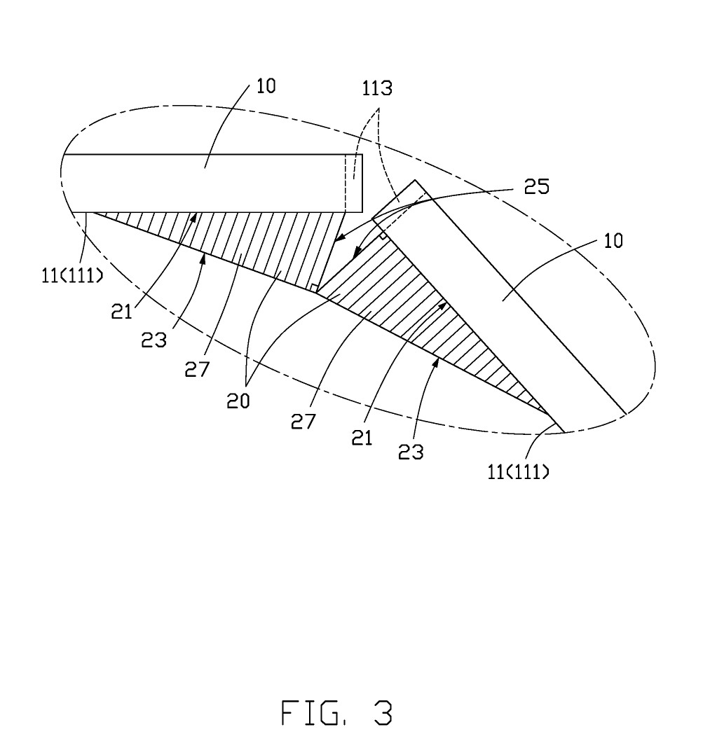

Referring to FIG. 3, a cross section of the image compensating element 20 is substantially triangular. The image compensating element 20 includes a light-incident surface 21, a light-emitting surface 23, and a connecting surface 25 connecting both the light-incident surface 21 and the light-emitting surface 23. The light-incident surface 21, the light-emitting surface 23, and the connecting surface 25 define the three sides of the triangle. In the present embodiment, both the light-incident surface 21 and the light-emitting surface 23 are flat surfaces. The connecting surface 25 may be a flat surface, a curved surface, or a surface including both a flat surface and a curved surface. In this embodiment, the connecting surface 25 is a flat surface. The light-incident surface 21 covers the display area 111 of the front surface 11 of the display device 10 but does not cover the border area 113. The light-emitting surface 23 intersects with the light-incident surface 21 to form an acute angle. The connecting surface 25 is connected between the light-emitting surface 23 and the light-incident surface 21.

Referring to FIG. 3, the two light-emitting surfaces 23 of the two image compensating elements 20 at the junction of two adjacent display devices 10 are coupled together. In the present embodiment, the two light-emitting surfaces 23 of the two image compensating elements 20 at the junction of every adjacent two display devices 10 are coupled together at an angle of less than 180 degrees. In other embodiments, the two light-emitting surfaces 23 of the two image compensating elements 20 at the junction of every adjacent two display devices 10 are couple together to define one plane. The image compensating element 20 includes a plurality of light guiding channels 27. Light guiding paths of the light guiding channels 27 are independent from each other and extend along a direction from the light-incident surface 21 toward the light-emitting surface 23. Each light guiding channel 27 is straight. The light guiding channels 27 are bundled together to form the image compensating element 20.

In one embodiment, each light guiding channel 27 is a light guiding fiber, and each light guiding fiber extends from the light-incident surface 21 toward the light-emitting surface 23. In the present embodiment, the light guiding fiber may be a plastic optical fiber, a quartz optical fiber, a glass optical fiber, or the like.

As shown in FIG. 1, when a user 50 views the display assembly 100, the user 50 is likely to be in an area facing a center of the front side of the display assembly 100. However, due to arrangement of the image compensating elements 20, non-uniform brightness between the infill display area and the main display area of each display device 10 may be noticeable. An optical axis direction of the light guiding channels 27 of the image compensating element 20 may be adjusted so that the optical axis direction (extending direction) of the light guiding channels 27 of the image compensating element 20 is pointing to the user 50 at a center portion of the display assembly 100. Images displayed with uniform brightness across the overall display may be viewed. A brightness of the image compensating element 20 and a brightness of other areas not covered by the image compensating element 20 being optimally adjusted.

In this embodiment, the display assembly 100 including three display devices 10 will be described as an example. As shown in FIG. 1, two image compensating elements 20 are positioned in the display area 111 of the display device 10 in the middle of the display assembly 100. One image compensating element 20 is positioned on the display device 10 on the left side, and one image compensating element 20 is positioned on the display device 10 on the right side. As shown in FIG. 3, in the present embodiment, the extending direction of the light guiding channels 27 of each image compensating element 20 on the display device 10 in the middle is perpendicular to the light-emitting surface 23, that is, the light-emitting surface 23 is perpendicular to the connecting surface 25. Thus, the optical axes direction (extending direction) of the light guiding channels 27 of the image compensating elements 20 in the middle is adjusted to point to the user 50. The extending direction of the light guiding channels 27 of the image compensating element 20 on the left side or on the right side extend substantially perpendicularly to the light-incident surface 21, that is, the light-incident surface 21 is perpendicular to the connecting surface 25. Thus, the optical axes direction (extending direction) of the light guiding channels 27 of the image compensating elements 20 on the left side and on the right side is adjusted to point to the user 50.

The extending directions of the light guiding channels 27 in each image compensating element 20 are substantially the same and arranged in an array. In the present embodiment, as shown in FIG. 3, for the image compensating element 20 on the display device 10 on the left side or the right side, a size of area of the light-incident surface 21 is smaller than a size of area of the light-emitting surface 23. A size of area of each light guiding channel 27 on the light-incident surface 21 is smaller than a size of area of the light guiding channel 27 on the light-emitting surface 23 and an end surface of each light guiding channel 27 on the light-emitting surface 23 forms a slope. For the image compensating element 20 on the central display device 10, a size of area of the light-incident surface 21 is greater than a size of area of the light-emitting surface 23. A size of area of each light guiding channel 27 on the light-incident surface 21 is greater than a size of area of the light guiding channel 27 on the light-emitting surface 23 and an end surface of each light guiding channel 27 on the light-incident surface 21 forms a slope.

Light from the main display area of the display device 10 is passed directly to the user, and the user can view all of the main display area. Light from the pixels of the infill display area of the display device 10 enters into the light guiding channels 27 from the light-incident surface 21 of the compensating element 20 and is emitted from the light-emitting surface 23 of the image compensating element 20. The juxtapositioning of adjacent image compensating elements 20 means that when the viewer views the display screen of the display assembly 100, the border areas 113 at the junction of adjacent display devices 10 are effectively not visible, so an uninterrupted display can be viewed. The image compensating element 20 extends images corresponding to the infill display areas at the junction of adjacent display devices 10 above the border areas 113, and the border areas 113 are shielded from view, thus a seamless display can be achieved. Since the image compensating elements 20 are used, overall images on the display devices 10 can be visually seamless.

### SECOND EMBODIMENT

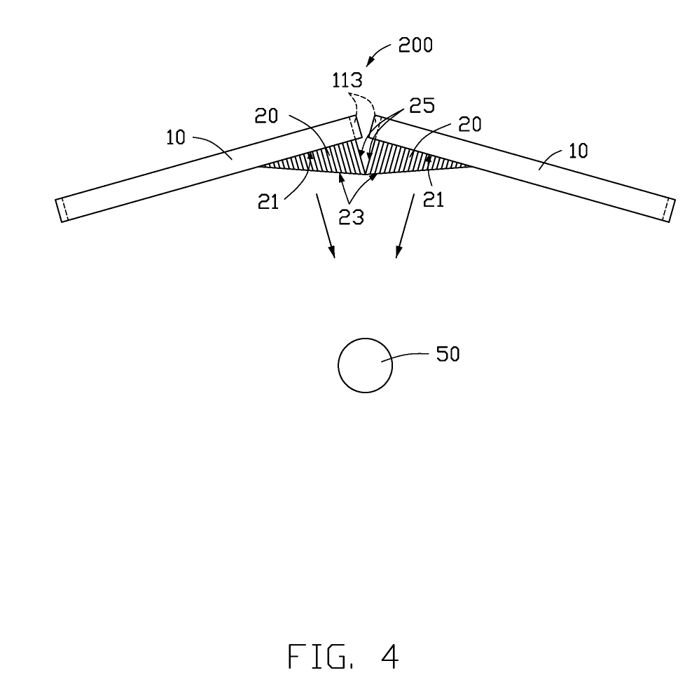

In this embodiment, a display assembly 200 including two display devices 10 will be described as an example. As shown in FIG. 4, one image compensating element 20 is positioned on each of the display devices 10. As shown in FIG. 4, in the present embodiment, the extending direction of the light guiding channels 27 of each image compensating element 20 is perpendicular to the light-incident surface 21. In other words, the light-incident surface 21 is perpendicular to the connecting surface 25. Thus, the optical axes direction (extending direction) of the light guiding channels 27 of each of the image compensating elements 20 is adjusted to be pointed to the user 50.

According to the present disclosure, no matter how many display devices 10 the display assembly includes, the optical axes direction (extending direction) of the light guiding channels 27 of each of the image compensating elements 20 can be adjusted to optimally pointing to the user 50. Hence, the brightness of the image compensating element 20 and the brightness of the area not covered by the image compensating element 20 are optimally adjusted. Furthermore, an optimum distance between the user and a middle of the display assembly 100 can be defined according to the present disclosure, and direction of the optical axes is adjustable depending on the distance between the user and the middle of the display assembly 100.

In one embodiment, the display device 10 can be a liquid crystal display device, an organic light emitting diode display device, a micro-light emitting diode display device, and the like.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A display assembly, comprising:
at least two display devices, each of the at least two display devices comprising a front surface adapted for displaying image, the front surface defining a display area and a border area outside the display area, two front surfaces of every adjacent two of the display devices intersecting with each other at an angle of less than 180 degrees ; and
two image compensating elements at a junction of every adjacent two of the display devices, each of the two image compensating elements being arranged on the front surface of one of the adjacent two display devices;
each of the image compensating elements comprising a light-incident surface covering the display area, a light-emitting surface coupling to the light-incident surface, and a connecting surface coupling between the light-incident surface and the light-emitting surface;
wherein each of the image compensating elements comprises a plurality of light guiding channels; light guiding paths of the plurality of light guiding channels are independent from each other and extend along a direction from the light-incident surface toward the light-emitting surface; a direction of optical axes of the light guiding channels of each of the image compensating elements is pointed to a user facing to a middle of the display assembly.

2. The display assembly of claim 1, wherein the two light-emitting surfaces of the two image compensating elements at the junction of the adjacent two display devices are coupled together.

3. The display assembly of claim 2, wherein the light-emitting surfaces of the two image compensating elements at the junction of the adjacent two display devices are coupled to define a plane.

4. The display assembly of claim 1, wherein the display assembly comprises three display devices arranged one by one, the three display devices comprises one display device in the middle, one display device on the left side, and one display device on the right side.

5. The display assembly of claim 4, wherein the connecting surface is a flat surface.

6. The display assembly of claim 4, wherein for each image compensating element on the display device in the middle, the light-emitting surface intersects with the light-incident surface to define an acute angle, and extending direction of the light guiding channels is perpendicular to the light-emitting surface.

7. The display assembly of claim 6, wherein for each image compensating element on the display device in the middle, an area size of the light-incident surface is greater than an area size of the light-emitting surface.

8. The display assembly of claim 4, wherein for each image compensating element on the display device on the left side or on the right side, the light-emitting surface intersects with the light-incident surface to define an acute angle, and extending direction of the light guiding channels is perpendicular to the light-incident surface.

9. The display assembly of claim 8, wherein for each image compensating element on the display device on the left side or on the right side, an area size of the light-incident surface is smaller than an area size of the light-emitting surface.

10. The display assembly of claim 1, wherein the display assembly comprises two display devices.

11. The display assembly of claim 10, wherein one image compensating element is positioned on each of the two display devices; an extending direction of the light guiding channels of the one image compensating elements is perpendicular to the light-incident surface.
